(19) United States
(12) Patent Application Publication
(10) Pub. No.: US 2008/0291767 A1
(43) Pub. Date: Nov. 27, 2008

(54) MULTIPLE WAFER LEVEL MULTIPLE PORT REGISTER FILE CELL

(75) Inventors: Joseph S. Barnes, Chapel Hill, NC (US); Jagreet S. Atwal, Carrboro, NC (US); Kerry Bernstein, Underhill, VT (US); Robert J. Bucki, Cary, NC (US)

Correspondence Address: SCULLY, SCOTT, MURPHY & PRESSER, P.C., 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 11/751,315

(22) Filed: May 21, 2007

(51) Int. Cl. G11C 8/00; H01L 21/4763

(52) U.S. Cl. 365/230.05; 438/667; 257/E21.495

(57) ABSTRACT

A multi-port register file (e.g., memory element) is provided in which each read port of the register file is located in a separate wafer above and/or below the primary data storage element. This is achieved in the present invention by utilizing three-dimensional integration in which multiple active circuit layers are vertically stacked and vertically aligned interconnects are employed to connect a device from one of the stacked layers to another device in another stacked layer.

### FIELD OF THE INVENTION

The present invention relates to a semiconductor structure and a method of fabricating the same. More particularly, the present invention relates to a memory element that includes multiple write sources and read destinations.

### BACKGROUND OF THE INVENTION

In modern microprocessors, multi-port register file cells (i.e., a memory element with multiple write sources and multiple read destinations) are used for many architectural elements. A common element that the multi-port register file is used for is the General Purpose Register (i.e., GPR). The GPR memory array is used to hold data that is being operated on by different instructions from a host of possible units (pieces of the microprocessor) and/or threads (multiple instruction pipes). This is illustratively shown in FIG. 1 in which reference numeral 10 denotes the GPR, reference numeral 12 denotes a floating point unit (FDU), reference numeral 14 denotes an instruction unit (IU) and reference numerals 16A, 16B denote separate execution threads. In the drawing, the label “w” refers to a write data operation and the label “r” denotes a read data operation Each read and write data access can represent a port needed to each cell/memory element. FIG. 1 shows a need for a GPR design including three (3) read ports and four (4) write ports.

As the complexity of microprocessors increase, the number of possible units and/or threads needing to access the GPR is increasing. Most GPR's are on the larger cell count size, i.e., 64 entries, 70 bits. This means that as the port count grows so does the size of the cell and GPR, until the size becomes prohibited to meeting require cycle times of a modern day microprocessor.

The ability to have a larger number of ports (e.g., more than 6) in a GPR than the number in conventional microprocessors without impacting latency of the microprocessor will allow for more threads and units to have access to the GPR. This will allow for improved performance and latency of the microprocessor.

Power usage is also a growing concern for conventional microprocessors. As microprocessor complexity and MOS transistor counts grow, designers are working hard to find ways to lower AC and DC power. One power reduction technique is to power gate (turn off) parts of logic in the processors not being used. This is generally achieved by the use of footer/header devices to gate off the current to a power region in the microprocessor. The separate regions have different power routes associated with them. Often on the boundary or within these logic power islands are register files that are shared across functions/power islands that will be power gated separately. This is illustrated in FIG. 2 in which reference numeral 20 denotes a shared register file, reference numeral 22 denotes function A and reference numeral 24 denotes function B. The labels ‘w’ and ‘r’ have the same meaning as mentioned above.

To achieve power gating within the register file for function A and function B shown in FIG. 2, separately, there would have to be three separate VDD power grids, one for the function A ports of the register file, one for the function B ports, and one for the array data latches. Such an arrangement would take up the wiring resources that are hard to come by for multi-port register files due to multiple wordlines and bitlines to the cell.

In view of the above, there is a need for providing new and improved multi-port register file cells that avoid the drawbacks with prior art designs which are formed into a single wafer.

### SUMMARY OF THE INVENTION

The present invention provides a multi-port register file (e.g., memory element) in which at least each read port of the register file is located in a separate wafer above and/or below the primary data storage element. This is achieved in the present invention by utilizing three-dimensional integration in which multiple active circuit layers are vertically stacked and vertically aligned interconnects are employed to connect a device from one of the stacked layers to another device in another stacked layer.

By vertically stacking multiple active circuit layers with vertically aligned interconnects, at least each read port of a multi-port register file can be implemented on a separate layer above or below the primary data storage cell. This allows the multi-port register file structure to be implemented within the same area footprint as a standard register file cell, minimizing data read and write delays. Each write data line and read data bitline has a length associated with a simple two-dimensional register file cell array.

The inventive three dimensional approach allows the interconnect delays of write data lines and read bitlines for a multi-port register file to be comparable to those associated with the bitlines of a conventional two dimensional one read, one write register array. The write data and read bitline access is improved over the standard two dimensional approach for multi-port register arrays. The base register file (storage node) layer can be identical to a standard register file, eliminating the need for additional reticle enhancement techniques to be developed for a register file cell.

In general terms, the present invention provides a multi-port register file cell comprising:

at least one read data-containing wafer having a plurality of read data bitlines (i.e., read data circuitries) vertically stacked on a wafer including a storage element, said at least one read data-containing wafer and said wafer including said storage element are interconnected by at least one vertically conductive filled via hole.

In some instances, at least one write data line (i.e., write data circuitry) is present within the same wafer as the storage element. In yet other instances, the at least one write data line (i.e., write data circuitry) is located within the at least one read data-containing wafer. In further instances, the at least one write data line (i.e., write data circuitry) is present within its own wafer (i.e., a write data line-containing wafer) which is positioned above or below the at least one read data-containing wafer.

In one embodiment of the present invention, the multi-port register file cell comprises:

at least one first read data-containing wafer having a plurality of read data bitlines (i.e., read data circuitries) vertically stacked above a wafer including a storage element; and

at least one second read data-containing wafer having a plurality of read data bitlines vertically stacked below said wafer including said storage element, wherein said at least one first read data-containing wafer and said wafer including said storage element are interconnected by a first vertically conductive filled via hole, and said at least one second read data-containing wafer and said wafer including said storage element are interconnected by a second vertically conductive filled via hole.

In some instances, at least one write data line (i.e., write data circuitry) is present within the same wafer as the storage element. In yet other instances, the at least one write data line (i.e., write data circuitry) is located within the at least one read data-containing wafer. In further instances, the at least one write data line (i.e., write data circuitry) is present within its own wafer (i.e., a write data line-containing wafer) which is positioned above or below the at least one read data-containing wafer.

In the aforementioned embodiment, each storage node (e.g., true and compare) of the storage element (i.e., latch component) is connected through one of the vertically filled via holes to the one of the wafers including the read data bitlines. For example, the true node can be connected to the at least one first read data-containing wafer by the first vertically filled conductive filled via hole, while the compare node can be connected to the at least one second read data-containing wafer by the second vertically filled conductive wafer. Such an arrangement tends to reduce the load on the true and compare nodes of the storage element.

To further reduce the load on the true and compare nodes of the storage element, a true/complement generator buffer layer can be formed above the storage cell to isolate the load of multiple read ports from the storage nodes. This embodiment of the present invention is particular useful for large multi-port arrays (e.g., arrays with 16 read ports and two write ports).

In addition to the above, the present invention also provides a method of fabricating the inventive multi-port register file cell. The inventive method includes 3D integration and wafer bonding. Specifically, the inventive method includes the steps of:

vertically stacking at least one read data-containing wafer having a plurality of read data bitlines on a wafer including a storage element; and

interconnecting said at least one read data-containing wafer and said wafer including said storage element by forming at least one vertically conductive filled via hole.

In some instances, at least one write data line (i.e., write data circuitry) is present within the same wafer as the storage element. In yet other instances, the at least one write data line (i.e., write data circuitry) is located within the at least one read-data-containing wafer. In further instances, the at least one write data line (i.e., write data circuitry) is present within its own wafer (i.e., a write data line-containing wafer) which is positioned above or below the at least one read data-containing wafer.

### BRIEF DESCRIPTION OF THE DRAWINGS

FIG. 1 is a pictorial representation illustrating a typical prior art GPR memory array.

FIG. 2 is a pictorial representation illustrating a typical prior art shared register file including function A and function B.

FIG. 3A is a pictorial representation of the inventive 3D multi-port register file cell design, FIG. 3B is a pictorial representation of an embodiment of the present invention showing a 3D six (6) read, two (2) write multi-port register file cell.

FIG. 4 is a pictorial representation of a circuit layout for a sixteen (16) read, two (2) write register file cell.

FIG. 5A is a pictorial representation of a prior art 2D 16 read, 2 write register file cell whose circuit layout is shown in FIG. 4, while FIG. 5B is a representation of the inventive 3D 16 read, 2 write register file cell whose circuit layout is shown in FIG. 4

FIG. 6A is a pictorial representation of the power distribution of the prior art 2D 16 read, 2 write register file cell shown in FIG. 5A, while FIG. 6B is a pictorial representation of the power distribution of the inventive 3D16 read, 2 write register file cell shown in FIG. 5B.

FIG. 7A is a pictorial representation of a prior art multiple wafer layer with different domains connected via a bus interface in which the inventive multi-wafer register file cell is absent, while FIG. 7B is a pictorial representation of a multiple wafer layer with different domains connected via a bus interface in which the inventive multi-wafer register file cell is present.

FIGS. 8A-8D are pictorial representations (through cross sectional views) illustrating the basic processing steps of the present invention.

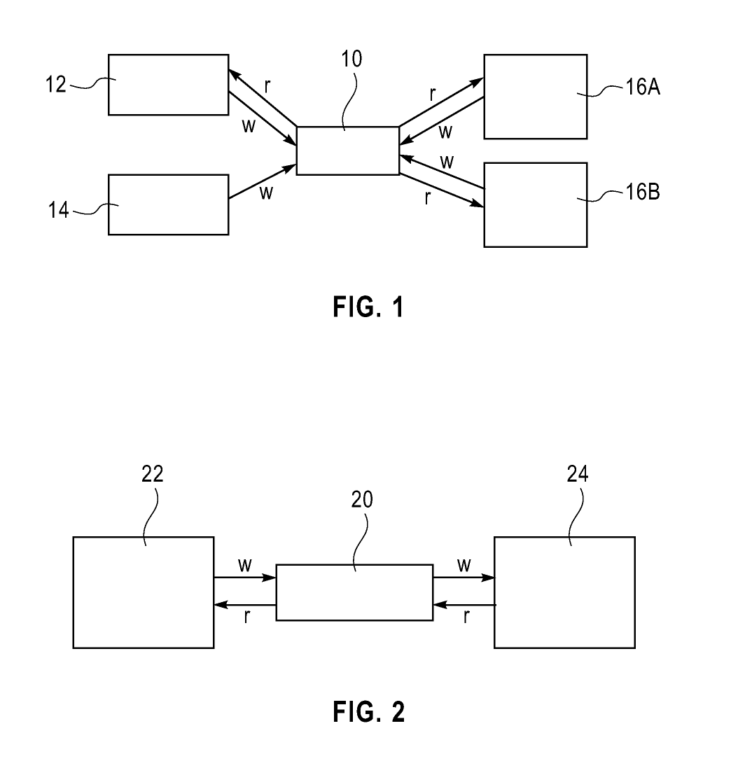

### DETAILED DESCRIPTION OF THE INVENTION

The present invention, which provides a multi-port register file cell and a method of fabricating the same, will now be described in greater detail by referring to the following discussion and drawings that accompany the present application. It is noted that the drawings are provided for illustrative purposes only. As such, the drawings included within the present application are not drawn to scale.

In the following description, numerous specific details are set forth, such as particular structures, components, materials, dimensions, processing steps and techniques, in order to provide a thorough understanding of the present invention. However, it will be appreciated by one of ordinary skill in the art that the invention may be practiced without these specific details. In other instances, well-known structures or processing steps have not been described in detail in order to avoid obscuring the invention.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

As stated above, the present invention provides a multi-port register file (e.g., memory element) in which each read port of the register file is located in a separate wafer above and/or below the primary data storage element which is present in another wafer. This is achieved in the present invention by utilizing three-dimensional integration in which multiple active circuit layers are vertically stacked and vertically aligned interconnects are employed to connect a device from one of the stacked layers to another device in another stacked layer.

In some instances, at least one write data line (i.e., write data circuitry) is present within the same wafer as the storage element. In yet other instances, the at least one write data line (i.e., write data circuitry) is located within the at least one read data-containing wafer. In further instances, the at least one write data line (i.e., write data circuitry) is present within its own wafer (i.e., a write data line-containing wafer) which is positioned above or below the at least one read data-containing wafer.

By vertically stacking multiple active circuit layers with vertically aligned interconnects, each read port of a multi-port register file can be implemented on a separate layer (wafer) above or below at least the primary data storage cell. This allows the multi-port register file structure to be implemented within the same area footprint as a standard RF cell; minimizing data read and write delays. Each write data line and read data bit line has a length associated with a simple two dimensional register file cell array. This three dimensional approach allows the interconnect delays of write data lines and read bitlines for a multi-port register file to be comparable to those associated with the bitlines of a conventional two dimensional 1 read, 1 write register array. The write data and read bitline access is improved over the standard 2D approach for multi-port register arrays. The base register file (storage node) layer can be identical to a standard register file, eliminating the need for additional reticle enhancement techniques to be developed for a register file cell.

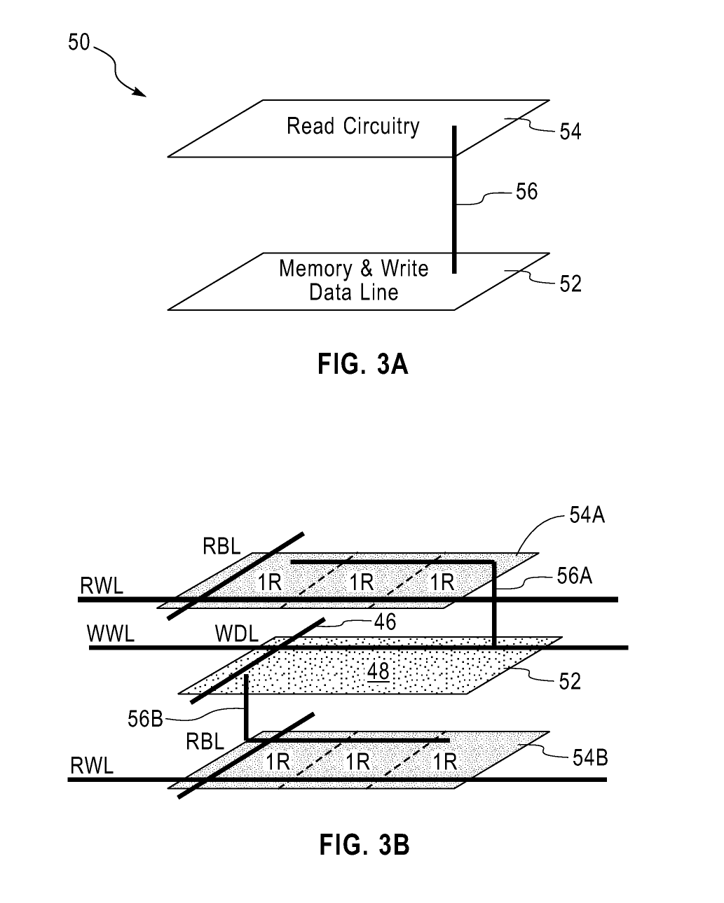

Reference is first made to FIG. 3A which illustrates the basic 3D multi-port register file cell design of the present invention. Specifically, FIG. 3A shows a 3D multi-port register file cell 50 of the present invention including at least one read data-containing wafer 54 having a plurality of read data bitlines vertically stacked on a wafer 52 including a storage element and at least one write data line. In the inventive structure, the at least one read data-containing wafer 54 and the wafer 52 including the storage element and said at least one write data line are interconnected by at least one vertically conductive filled via hole 56.

It is noted that FIG. 3A and the remaining drawings together with the details provided herein below are for an embodiment in which the read data bitlines are located within the same wafer as that of the storage element. Although such an embodiment is described and illustrated, the present invention also contemplates the read data bitlines in other wafers other than the wafer including the storage element. For example, the present invention contemplates the at least one write data line (i.e., write data circuitry) being located within the at least one read data-containing wafer. Additionally, the present invention also contemplates, the at least one write data line (i.e., write data circuitry) being present within its own wafer (i.e., a write data line-containing wafer) which is positioned above or below the at least one read data-containing wafer.

FIG. 3B show an embodiment of the present invention in the form of a 6 read, 2 write design. Specifically, the multi-port register file cell shown in FIG. 3B includes a first read data-containing wafer 54A having a plurality of read data bitlines (each labeled as 1R) vertically stacked above a wafer 52 including a storage element (48) and at least one write data line (46). A second read data-containing wafer 54B having a plurality of read data bitlines (each labeled as 1R) is shown vertically stacked below the wafer 52. In accordance with the drawing, the first read data-containing wafer 54B and the wafer 52 including the storage element 48 and the at least one write data line 46 are interconnected by a first vertically conductive filled via hole 56A. As also shown in FIG. 3B, the second first read data-containing wafer 54B and the wafer 52 including the storage element 48 and the at least one write data line 46 are interconnected by a second vertically conductive filled via hole 56B.

It is observed that in FIG. 3B, the terms “RBL” denotes the read bitline, ‘RWL” denotes the “read wordline”, “WWL” denotes the write wordline”, “WDL” denotes the write data lines, “true” denotes the true storage node and “comp” denotes the compare storage node.

On a single wafer design, the elements defined above and depicted in FIGS. 3A and 3B would be all laid out together. So the area footprint would be that of storage node plus the area associated with write ports plus the area associated with the read ports. In the innovative solution, these elements are located on different wafers. As indicated above, the storage cell and the write port circuitry are located on one wafer, and the multiple read port circuitry on another wafer or wafers. Multiple read ports can be added on active layers bonded and aligned atop the original layer. Each layer can support a multiple read ports and/or write ports.

Storage nodes of the storage element (e.g., latch component), labeled true and comp, are connected vertically through vias. An excessive load on the storage nodes can impair write ability; in order to minimize this effect one could send the true node to read ports on the wafer located above the wafer including the combined storage element and write circuitry, and the comp node can be connected to read ports on the wafer beneath the one including the combined storage element and write circuitry.

To further reduce the load on the true/comp nodes for large multi-port arrays (e.g., an array with 16 read ports and 2 write port), a true/complement generator buffer (not shown) can be inserted in a layer above the storage cell to isolate the load of multiple read ports from the storage nodes. Adding buffers to an array cell, along with large number of read ports would create havoc on the read timing because of large area footprint in 2D, but in 3D, the ability to separate the ports onto different wafers using our innovative approach, allows feasibility of register files, which would not be possible previously.

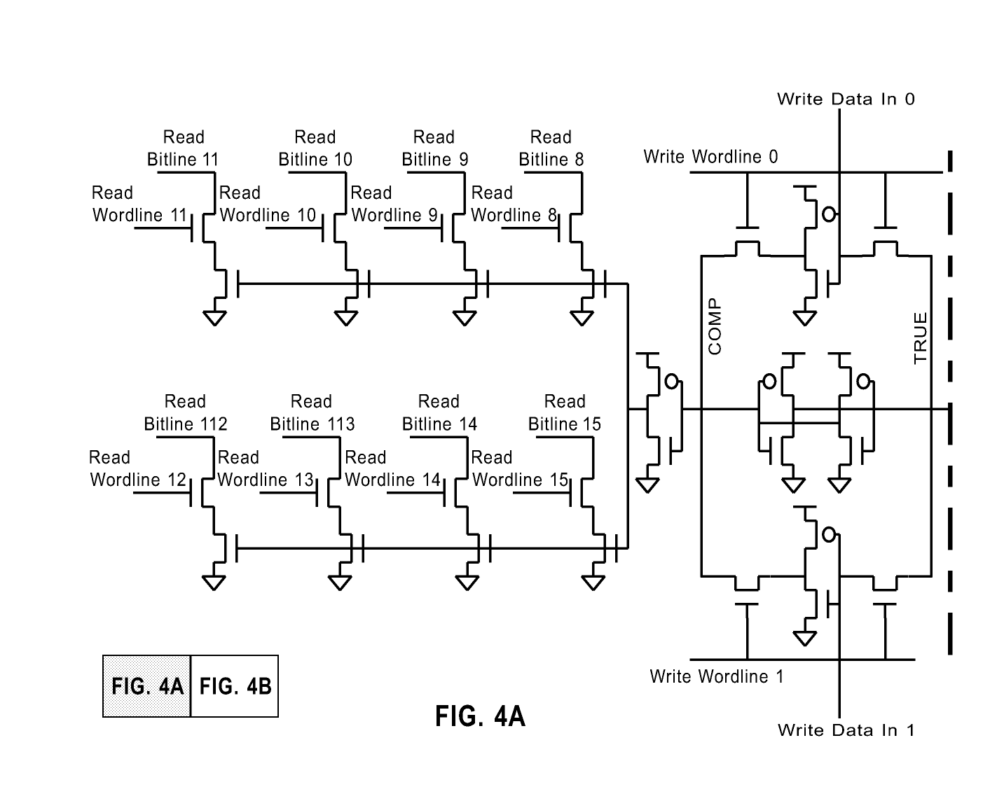

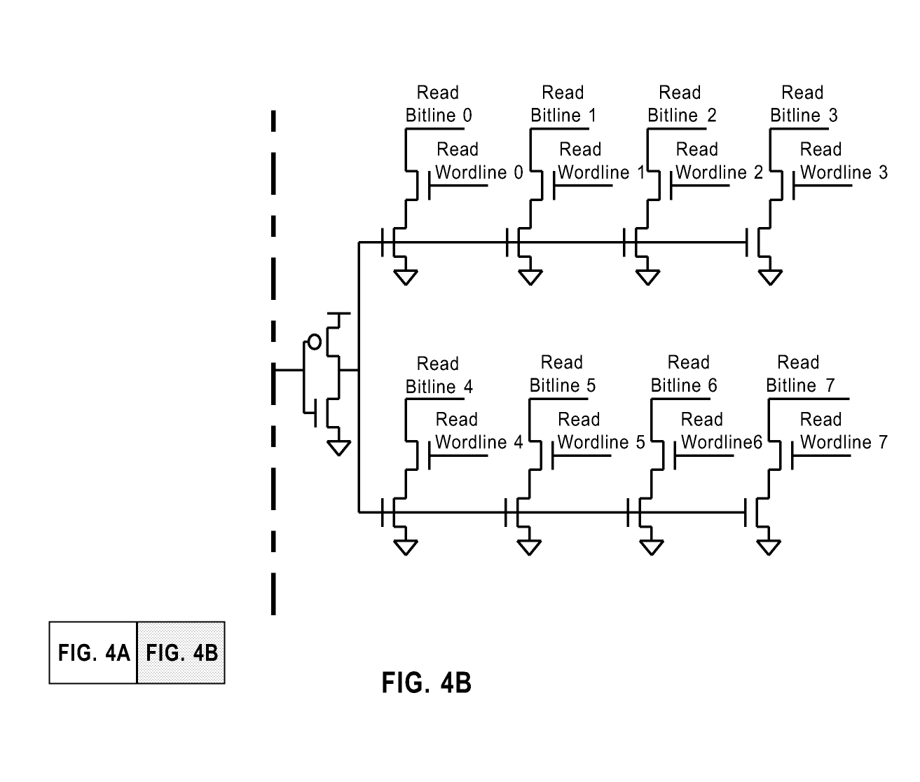

FIG. 4 shows a cell layout schematic of 16 read, 2 write register file cell. In this drawing, “true” denotes the true storage node and “comp” denotes the compare storage node.

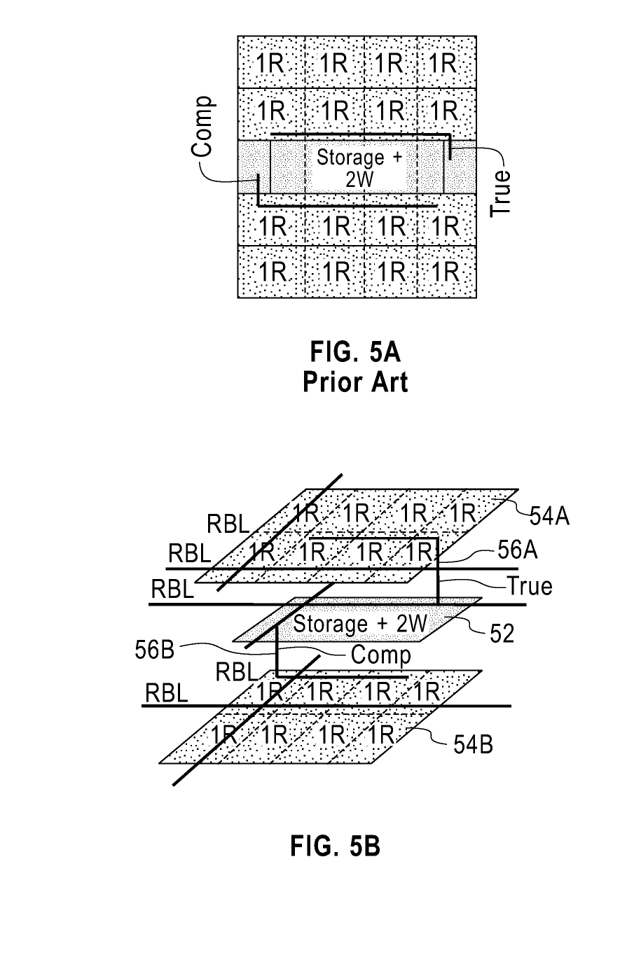

FIG. 5A shows a prior art 2-D cell layout and FIG. 5B shows the wafer configuration in 3D technology using the inventive structure and method. It is observed that the overall footprint area (bird's eye view) is much less in FIG. 5B in comparison to FIG. 5A. It is also noted that the overall area footprint for the inventive cell layout shown in FIG. 3B is also reduced.

Smaller area of the resultant register file cell has many benefits including, for example: shorter bitlines for read; shorter data lines for write; and shorter word lines (write and read). All of these benefits result in a register file structure that is easier (faster) to write, and a marked improvement read timing path because of shorter local and global bit lines.

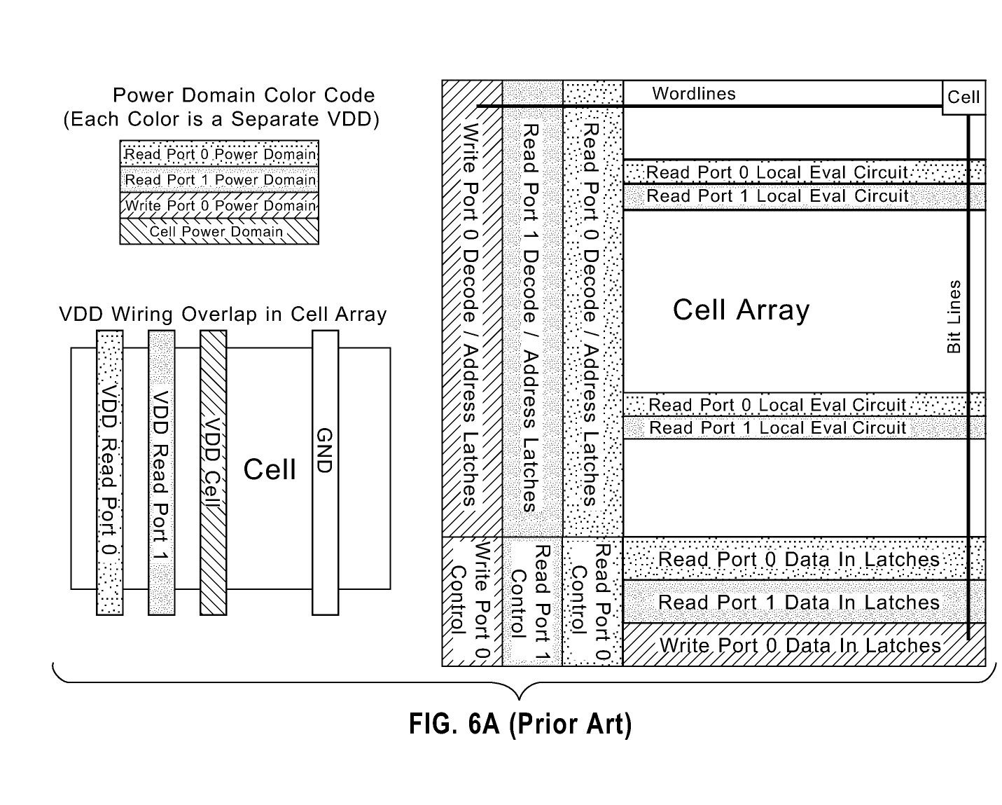

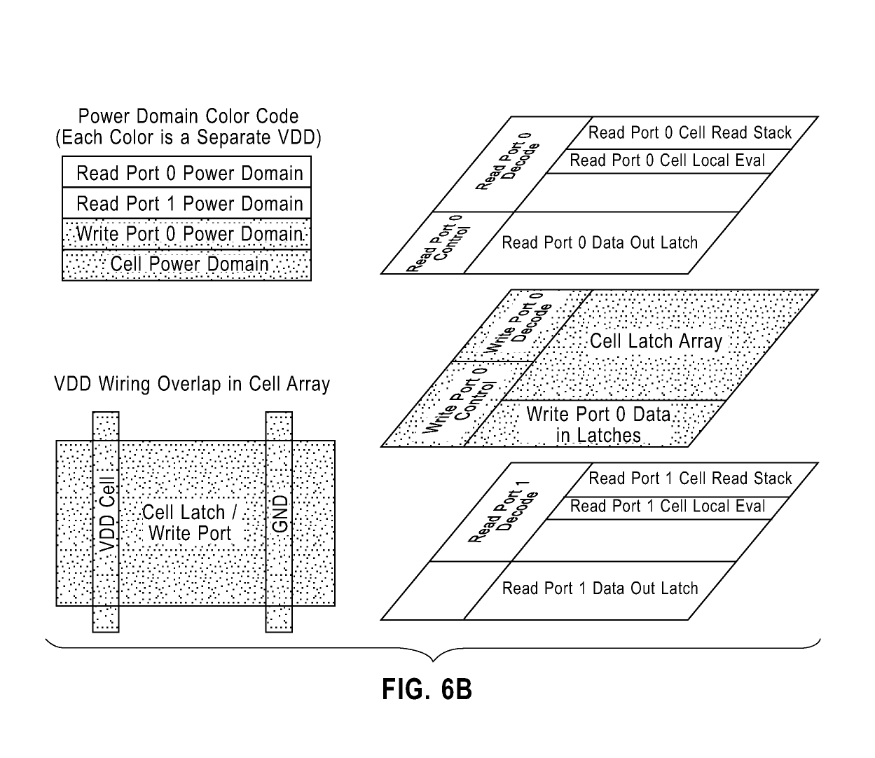

On a single wafer, the register file circuits are so closely laid out, that it is almost impossible to give separate voltage domains to these elements without significantly increasing the area footprint, and also leads to added complexity for power distribution and the access area for power wires. FIG. 6A shows power distribution on a single wafer for a 2 read, 1 write design. FIG. 61B shows power distribution of 2r1w register file on a multi-wafer. This reduces wiring congestion from multiply power supplies by placing the power and associated logic for each domain on its own wafer level reducing the overall foot-print of the design. The power on each level and function can then be controlled separately without impacting the performance or area of other ports.

In a multi-wafer design, read ports lie physically on a separate wafer (or wafers) than the storage nodes and the write port. Controlling power distribution can be done on a wafer-by-wafer basis; i.e., it is now possible to have read circuitry, write circuitry, and storage circuitry with lower or higher voltages with respect to each other. Timing critical paths could easily be supplied with a higher voltage, or vice versa non-critical circuits (higher margin) could be given a lower voltage. There may be a need of a voltage translator if storage cell is on a lower voltage than read circuits, since true and complement lines are driven from the storage cell to the read circuitry. Separation of read ports and storage plus write ports onto different wafers also allows for more granular power gating.

Another advantage of this split is to completely turnoff read and/or write circuitry, where architecturally match circuits are not being utilized, and the storage node core can be used as a standard register. The inventive structure and method provide flexibility for more innovative architectural solutions.

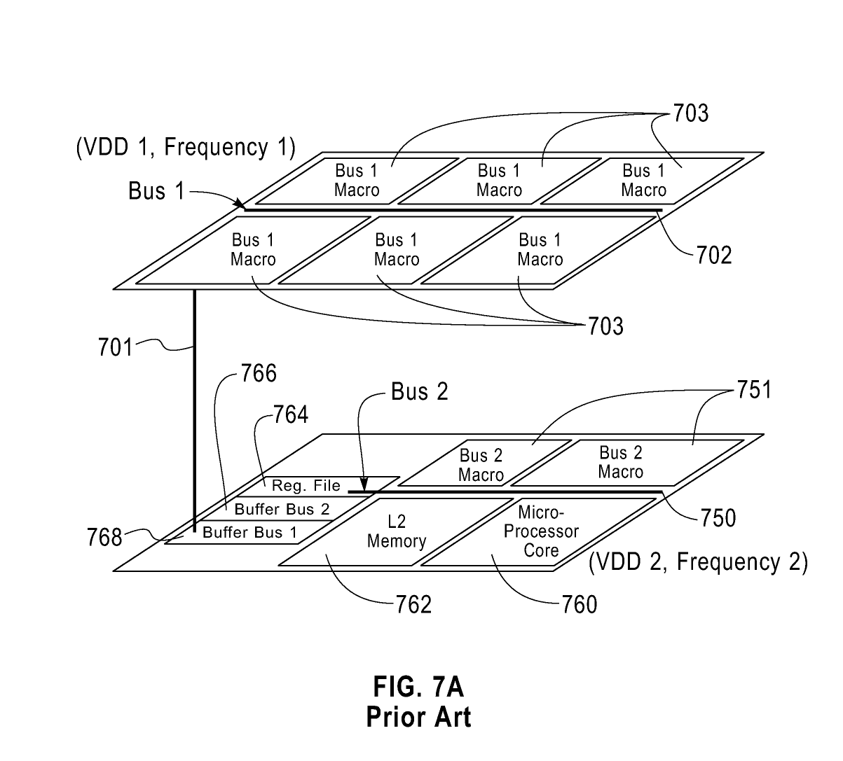

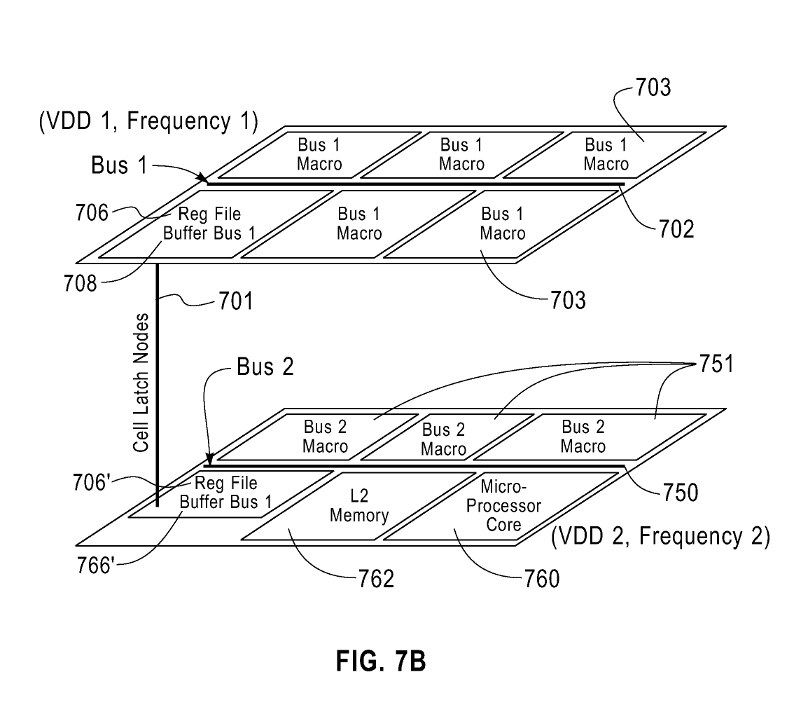

In multi-wafer technologies there is a desire to reuse IP (macros/units) from different technologies or that reside in a different functional, frequency, and/or power domains. In some of these cases there is a need for a bus interface between two bus domains, the same would be need for a 2-D technology. In many cases register file arrays are used to buffer data from one bus domain to the other and vice-versa, See FIG. 7A for example. This requires that the 2 bus domains reside together in the same register file macro. In a 3-D multi-wafer technology as provided by the present invention, this would require both bus domains (power and frequency) to reside on a single wafer where one domain may be possible, as shown in FIG. 7B. In FIG. 7A, 702 denotes a first bus, 703 denotes a first bus macro, 750 denotes a second bus, 751 denotes a second bus macro, 760 denotes a microprocessor core, 762 denotes a memory element, 764 denotes a register file, 766 denotes a second buffer layer for the second bus, 768 denotes a first buffer layer for the first bus. In FIG. 7B, the 702 denotes a first bus, 703 denotes a first bus macro, 706 denote a register file, 708 denotes a first buffer layer, 750 denotes a second bus, 751 denotes a second bus macro, 760 denotes a microprocessor core, 762 denotes a memory element, 706′ denotes a register file and 766′ denotes a second buffer layer for the second bus.

When a small part of one domain resides in another domain (701), the variations (process, frequency etc.) of separated part increase relative to having it reside on larger domain space. This requires more margins to be placed in the register file macro decreasing the macro's performance/system performance and reducing the yield of the chip. Using the innovative solution of multi-wafer register file, it is possible to keep domains separate on each wafer, using only the register file (specifically storage nodes) to do any inter-domain communication, as shown in FIG. 7B.

The actual area and timing differences between single wafer register file vs. multi-wafer register file designs is now quantified using a multi-port register file cell of the invention configured as a 9 read, 4 write register file cell. In such a layout, all elements (read, write, data inverter, and storage node) are densely integrated. The dimensions of this dense layout are 4.104 μm (width), and 3.04 μm (h). In a multi-wafer approach to 9r4w cell, four wafers are utilized, in which circuitry is separated as such—wafer 0 includes 5 read ports, wafer 1 includes the storage node plus one write port and true data inverter, wafer 2 includes two write ports and comp data inverter, and lastly wafer 4 includes four read ports. The connections between the wafers are made using vertical interconnects. Out of all the wafers, the wafer 1 has the most circuitry and has the largest area (2.736 μm wide and 1.52 μm high), so wafer 1 will dictate the overall dimensions of the array, due to need for the vertical aligned wafer to wafer interconnect between cell parts.

Comparing the area of the 9r4w dense vs. the 9r4w modular, the applicants observed a 33% reduction in width and a 50% reduction in the height. As such, timing improvements can be obtained in paths that are vertically and horizontally inclined across the cells. Some of these vertically timed paths are (i) Read: local bit line readout, local receiver, global bit line readout; and (ii) Write data arrival time. Comparing the widths 4.104 μm for the dense arrays vs. 2.736 μm in the 3D integrated array (per bit cell column), it was observed that the width is half ⅔ of its original size. The height of the cell is by half from 3.04 μm tall in the 2-D implementation to 1.52 μm tall in a 3-D implementation.

The reduced width has many timing benefits namely:

Read and Write word line propagation delay is reduced
a. For a 32 bit array in 45 nm technology with wire 1.5× spacing and 1.5 width, a 3.2 pico second improvement was observed.

Decode Path Delay reduction
a. In multi-wafer designs the control logic for address and decode is separated per wafer, so accumulative area reduction for port controls lends to approximately 5 pico seconds reduction in the decode path delay.

The reduced height has many timing benefits namely:

Read Path timing improvement (Wordline Rising to Cross-Coupled Nand latching)
a. For a 64 entry array core, the applicants observed that the dense 2D 9r4w took 112 pico seconds vs. 84 pico seconds for the inventive 3D 9r4w; an improvement of 28 pico seconds.

Write Data Propagation Delay reduction
a. For a 64 entry array core, doing a write to the farthest cell took 53 pico second in the 2D dense 9r4w write vs. 38 pico seconds in the 3D Multi-wafer 9r4w design

Quantifying the delay improvements in the 3D multi-wafer register file vs. the 2D register file for a 9r4w large multi-port design; the 3D multi-wafer shows significant timing improvements in both read and write ports, while allowing more granularity per port.

In order to achieve the multi-port register file cell of the present invention, three-dimensional (3D) integration and packaging technology (also know as vertical integration) is employed. In such a technology, multiple layers of active devices are stacked with vertical interconnection between the layers to form 3D integrated circuits (ICs). 3D ICs provide potential performance advancements even in the absence of continued device scaling, as each transistor in a 3D IC can access a greater number of nearest neighbors and each circuit functional block has higher bandwidth. Other benefits of 3D ICs are improved packing density, noise immunity, improved total power due to reduced wire length and hence lower load capacitance, potential performance benefits, and ability to implement added functionality (mixed technologies).

A preferred embodiment for the fabrication of wafer scale 3D Integration is accomplished via the bonding of independently-fabricated layers of a semiconductor-on-insulator substrate. Each layer is designed and checked as an independent chip with its own metallization layers, but with the addition of vacant vertical via channels for the later placement of the vertical via. Upper layers are all processed to their last metal, and a temporary clear glass handle is glued to the top. The bottom of the wafer is then polished, removing the back silicon, and most of the SOI buried oxide. This wafer is then aligned and then Si-bonded to the top of the base layer using low temperature and high pressure bonding. The handle substrate is then removed by either laser-ablating or dissolving the adhesive. The vertical via holes are etched down through the upper layer, reaching the base layer wiring underneath; these vias are then lined and filled in much the same process as a conventional metal via. A final wiring layer is then applied on top of the completed vertical via, and either terminal metals or another silicon layer may be placed on top.

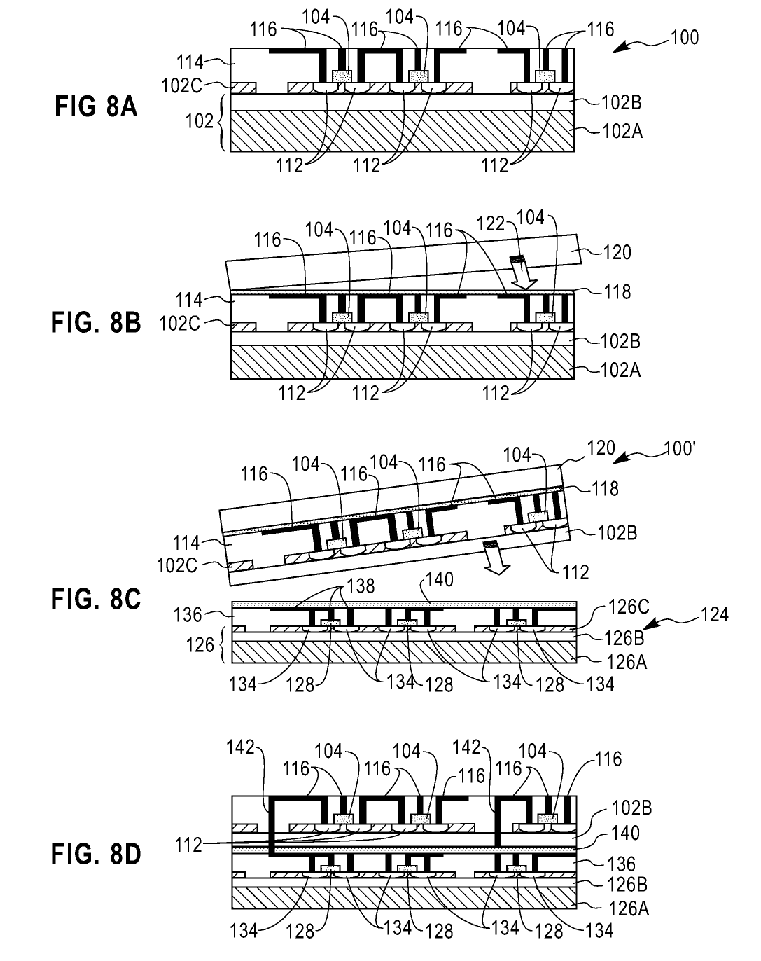

Reference is now made to FIGS. 8A-8D which are pictorial representations illustrating the basic processing steps which are employed in the present invention for fabricating the inventive multi-port, multi-wafer register file cell. In these drawings, two wafers are shown, by way, of example. Although two wafers are used in these drawings the present invention typically utilizes at least three wafers. In fact, the present invention contemplates cases where pluralities of wafers are stacked one on top of the other utilizing 3D integration.

Reference is first made to FIG. 5A which illustrates a first structure (i.e., processed wafer) 100 that can be employed in the present invention. The first structure (or first wafer) 100 includes a processed SOI substrate 102 which includes a bottom semiconductor layer 102A, a buried insulating layer 102B and a top, active semiconductor layer 102C. As is shown, the top, active semiconductor layer 102C includes a plurality of semiconductor devices, for example field effect transistors 104 located upon and within the top, active semiconductor layer 102C. Note that the top, active semiconductor layer has been patterned as shown in FIG. 5A.

The top and bottom semiconductor layers 102C and 102A, respectively, comprise any semiconductor material including for example, Si, SiGe, SiC, SiGeC, GaAs, InP, InAs, and multilayers thereof. Preferably, the top and bottom semiconductor layers 102C and 102A, respectively, comprise Si. The buried insulating layer 102B comprises a crystalline or non-crystalline dielectric including oxides, nitrides, oxynitrides and multilayers thereof. Preferably, the buried insulating layer 102B comprises an oxide.

Each transistor 104 includes at least a gate dielectric (such as an oxide) and a gate conductor (such as doped polysilicon or a metal gate). The plurality of transistors may also include at least one sidewall spacer (not shown) and source/drain regions 10 that are located within the top, active semiconductor layer 102C. The SOI substrate, and the components of the transistors are well known to those skilled in the art. Also, methods of making SOI substrates as well field effect transistors are also well known to those skilled in the art. In order not to obscure the invention details concerning the foregoing elements have been omitted.

The structure shown in FIG. 7A also includes at least one dielectric material 114 which includes conductive filled openings 116 (in the form of vias and vias/lines) which extend to the top of the gate conductor as well as the source/drain regions 112. The at least one dielectric material 114 and the conductive filled openings 116 represent an interconnect structure (or wiring structure) that is made using conventional techniques well known in the art. The at least one dielectric material 114 comprises any well known dielectric including, for example, SiO₂, silsesquioxanes and C-doped oxides. Porous as well as non-porous dielectric materials can be used. The conductive filled openings 116 comprise a conductive material including, for example, W, Al, Cu and alloys such as AlCu. A liner material such as TiN or TaN may be present in the conductive filled openings 116.

After providing the structure shown in FIG. 8A, an optional adhesive or bonding aid layer 118 is formed on the upper exposed surface of the interconnect structure providing the structure shown in the lower portion of FIG. 5B. The optional adhesive or bonding aid layer 118 comprises, for example, an oxide or a silane. The optional adhesive or bonding aid layer 118 is formed utilizing a conventional deposition process including, for example, chemical vapor deposition (CVD), plasma enhanced chemical vapor deposition (PECVD), or spin-on coating. FIG. 8B also shows the presence of a handling substrate 120 which is brought into contact with the uppermost surface of the structure 100, i.e., either the optional adhesive or bonding layer 118, if presence, or directly to the surface of the dielectric material 114. Arrow 122 indicates the application to the uppermost surface of structure 100.

Next, and as also illustrated in FIG. 8C, the bottom semiconductor layer 102A of the SOI substrate is removed utilizing a planarization process such as chemical mechanical polishing (CMP). During this planarization process, the buried insulating layer 102B is typically thinned from an initial thickness to a first thickness. The structure is now referred to as first structure (or first wafer) 100′.

Before, during or after thinning, a second structure (i.e., processed wafer) 124 is formed utilizing standard processing techniques that are well known to those skilled in the art. The second structure 124 includes an SOI substrate 126 which includes a bottom semiconductor layer 126A, a buried insulating layer 126B and a top, active semiconductor layer 126C. Note that the bottom semiconductor layer 126A, the buried insulating layer 126B and the top, active semiconductor layer 126C may comprise the same or different materials as used above for the SOI substrate 102.

The second structure 124 also includes a plurality of field effect transistors 128 that are located upon and within the top, active semiconductor layer 126C. The plurality of transistors 128 of the second structure 124 includes a gate dielectric, a gate conductor, and source/drain regions 134. The second structure 124 also includes at least one dielectric material 136 that includes conductive filled openings 138 that are formed in the at least one dielectric material 136. The at least one dielectric material 136 and the conductive filled openings 138 may comprise the same or different materials as their corresponding elements described above in the first structure. An oxide layer 140 may optionally be formed atop the dielectric material 136 of the second structure.

Next, and as illustrated in FIG. 5C, a desired surface of the second structure 124 is brought into intimate contact with a desired surface of the first structure 100′ as is processed in FIG. 8B. Typically, the thinned buried oxide layer 102B of the first structure 100′ is brought into intimate contact with the oxide layer 140 of the second structure. Bonding is then performed utilizing any conventional bonding technique known to those skilled in the art. For example, the bonding may be achieved utilizing a nominal room temperature bonding process (temperature from about 20° to about 40° C.) or bonding may be achieved at higher temperatures. Various post bonding anneal processes may be used to enhance the bonding strength.

After bonding at least the first and second structures 100′ and 126 together, the handling substrate 120 is removed by a conventional technique including, for example laser ablation, planarization, or etching. The adhesive or bonding aid layer 118 is typically also removed by this step of the present invention.

Other structures (i.e., processes wafers) can be formed atop the second structure as desired utilizing the same basic processing techniques as described above. The other structures include other read ports of the inventive register file cell. For the sake of clarity, the drawings depict only a single read port being vertically stacked upon a wafer including a memory element and at least one write port circuitry. As will be understood by those skilled in the art, a plurality of wafers including read ports can be vertically stacked atop the structure shown in FIG. 8c after the handling substrate 120 has been removed.

Vertical via holes are then formed by lithography and etching down from the now exposed upper surface layer of dielectric material 114 reaching the conductive filled openings 138 of the second structure 126. The vias are then lined with a liner material (e.g., TiN, TaN or WN) and the remaining portion of the vertical via holes is filled with a conductive material. FIG. 8D illustrates the final structure including the conductive filled vertical via holes 142. Conventional interconnect process can then be performed as desired. When multiple read ports are vertical stacked upon the wafer including the storage element and the write port circuitry, the conductive filled vertical via holes would connect the compare transistors present in the uppermost wafer to then other compare transistors in the underlying wafers as well as to the storage element transistors in the lowest most wafer.

While the present invention has been particularly shown and described with respect to preferred embodiments thereof it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A multi-port register file cell comprising:
at least one read data-containing wafer having a plurality of read data bitlines vertically stacked on a wafer including a storage element, said at least one read data-containing wafer and said wafer including said storage element are interconnected by at least one vertically conductive filled via hole.

2. The multi-port register file cell of claim 1 further comprising at least one write data line present within the same wafer as the storage element.

3. The multi-port register file cell of claim 1 further comprising at least one write data line present within the at least one read data-containing wafer.

4. The multi-port register file cell of claim 1 further comprising at least one write data line present within its own wafer that is positioned above or below the at least one read data-containing wafer.

5. The multi-port register file cell of claim 2 wherein said at least one read data-containing wafer comprises at least one first read data-containing wafer atop said wafer including said storage element and said at least one write data line and at least one other read data-containing wafer below said wafer including said storage element.

6. The multi-port register file cell of claim 5 wherein said at least one read data-containing wafer contains three read bitlines, said wafer includes 2 write data lines, and said at least one other read data-containing wafer includes three read bitlines.

7. The multi-port register file cell of claim 5 wherein said storage element includes a true node and compare node, said true node is vertically connected to said at least one read data-containing wafer by a first conductively filled via and said compare node is vertically connected to said at least one other read data-containing wafer by a second conductively filled via.

8. The multi-port register file cell of claim 5 wherein said at least one read data-containing wafer contains eight read bitlines, said wafer includes 2 write data lines, and said at least one other read data-containing wafer includes eight read bitlines.

9. The multi-port register file cell of claim 1 wherein said at least one read data-containing wafer is a single wafer including two read bitlines and said wafer including said storage element further includes one write data line.

10. The multi-port register file cell of claim 1 further comprising a plurality of bus macros in each of said at least one read data-containing wafer and said wafer including said storage element.

11. A multi-port register file cell comprising:
at least one first read data-containing wafer having a plurality of read data bitlines vertically stacked above a wafer including a storage element; and
at least one second read data-containing wafer having a plurality of read data bitlines vertically stacked below said wafer including said storage element, wherein said at least one first read data-containing wafer and said wafer including said storage element are interconnected by a first vertically conductive filled via hole, and said at least one second first read data-containing wafer and said wafer including said storage element are interconnected by a second vertically conductive filled via hole.

12. The multi-port register file cell of claim 11 further comprising at least one write data line present within the same wafer as the storage element.

13. The multi-port register file cell of claim 11 further comprising at least one write data line present within one of said read data-containing wafers.

14. The multi-port register file cell of claim 11 further comprising at least one write data line is present within its own wafer that is positioned above or below one of the read data-containing wafers.

15. The multi-port register file cell of claim 12 wherein said at least one first read data-containing wafer contains three read bitlines, said wafer including said storage element contains 2 write data lines, and said at least one second read data-containing wafer includes three read bitlines.

16. The multi-port register file cell of claim 12 wherein said at least one first read data-containing wafer contains eight read bitlines, said wafer including said storage element contains 2 write data lines, and said at least one second read data-containing wafer includes eight read bitlines.

17. The multi-port register file cell of claim 11 wherein said storage element includes a true node and compare node.

18. The multi-port register file cell of claim 17 wherein said true node is vertically connected to said at least one first read data-containing wafer by said first conductively filled via and said compare node is vertically connected to said at least one second read data-containing wafer by said second conductively filled via.

19. The multi-port register file cell of claim 11 further comprising a plurality of bus macros in each of said wafers.

20. A method of fabricating a multi-port register file cell comprising:
vertically stacking at least one read data-containing wafer having a plurality of read data bitlines on a wafer including a storage element; and
interconnecting said at least one read data-containing wafer and said wafer including said storage element by forming at least one vertically conductive filled via hole.
